(19) United States
(12) Patent Application Publication
(10) Pub. No.: US 2025/0241139 A1
(43) Pub. Date: Jul. 24, 2025

(54) DISPLAY DEVICE

(71) Applicant: Japan Display Inc., Tokyo (JP)

(72) Inventors: Akinori KAMIYA, Tokyo (JP); Hiraaki KOKAME, Tokyo (JP); Keiji HORIKAWA, Tokyo (JP)

(73) Assignee: Japan Display Inc., Tokyo (JP)

(21) Appl. No.: 18/981,714

(22) Filed: Dec. 16, 2024

(30) Foreign Application Priority Data
Jan. 18, 2024 (JP) 2024-006221

(51) Int. Cl. H10K 59/122; H10K 59/80

(52) U.S. Cl. CPC H10K 59/122; H10K 59/873

(57) ABSTRACT

According to one embodiment, a display device includes a first lower electrode, a partition which has a lower portion and an upper portion, a first stacked film which includes a first organic layer and a first upper electrode, a first barrier layer which is provided on the first stacked film, extends to an upper side of the partition, forms a gap between the first barrier layer and the upper portion, and is formed of a first inorganic insulating material, a first sealing layer which overlaps the first barrier layer and is formed of a second inorganic insulating material which is different from the first inorganic insulating material, and a resin layer which covers the first sealing layer and with which the gap is filled.

### CROSS-REFERENCE TO RELATED APPLICATIONS

This application is based upon and claims the benefit of priority from Japanese Patent Application No. 2024-006221, filed Jan. 18, 2024, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a pixel circuit including a thin-film transistor, a lower electrode connected to the pixel circuit, an organic layer which covers the lower electrode, and an upper electrode which covers the organic layer. The organic layer includes functional layers such as a hole transport layer and an electron transport layer in addition to a light emitting layer.

In the process of manufacturing such a display element, a technique which prevents the reduction in reliability has been required.

### BRIEF DESCRIPTION OF THE DRAWINGS

FIG. 1 is a diagram showing a configuration example of a display device DSP.

FIG. 2 is a diagram showing an example of the layout of subpixels SP1, SP2 and SP3.

FIG. 3 is the schematic cross-sectional view of the display device DSP along the A-B line of FIG. 2.

FIG. 4 is a diagram for explaining the manufacturing method of the display device DSP.

FIG. 5 is a diagram for explaining the manufacturing method of the display device DSP.

FIG. 6 is a diagram for explaining the manufacturing method of the display device DSP.

FIG. 7 is a diagram for explaining the manufacturing method of the display device DSP.

FIG. 8 is a diagram for explaining the manufacturing method of the display device DSP.

FIG. 9 is a diagram for explaining the manufacturing method of the display device DSP.

FIG. 10 is a diagram for explaining the manufacturing method of the display device DSP.

FIG. 11 is a diagram for explaining the manufacturing method of the display device DSP.

FIG. 12 is a diagram for explaining the manufacturing method of the display device DSP.

FIG. 13 is a diagram for explaining the manufacturing method of the display device DSP.

FIG. 14 is a diagram for explaining the manufacturing method of the display device DSP.

FIG. 15 is a diagram for explaining the manufacturing method of the display device DSP.

FIG. 16 is a diagram for explaining the manufacturing method of the display device DSP.

FIG. 17 is a diagram for explaining the manufacturing method of the display device DSP.

FIG. 18 is a diagram for explaining the manufacturing method of the display device DSP.

FIG. 19 is a diagram for explaining the manufacturing method of the display device DSP.

FIG. 20 is a diagram for explaining the manufacturing method of the display device DSP.

FIG. 21 is a cross-sectional view showing another configuration example of the display device DSP.

FIG. 22 is a cross-sectional view showing another configuration example of the display device DSP.

FIG. 23 is a cross-sectional view showing another configuration example of the display device DSP.

FIG. 24 is a cross-sectional view showing another configuration example of the display device DSP.

### DETAILED DESCRIPTION

Embodiments described herein aim to provide a display device which can prevent the reduction in reliability.

In general, according to one embodiment, a display device comprises a substrate, a first lower electrode provided above the substrate, an inorganic insulating layer which covers a peripheral portion of the first lower electrode, a partition which has a lower portion provided on the inorganic insulating layer and formed of a conductive material, and an upper portion provided on the lower portion and protruding from a first side surface of the lower portion and a second side surface located on a side opposite to the first side surface, a first stacked film which includes a first organic layer being in contact with the first lower electrode, and a first upper electrode provided on the first organic layer and being in contact with the lower portion, a first barrier layer which is provided on the first stacked film, is in contact with the first side surface, extends to an upper side of the partition, forms a gap between the first barrier layer and the upper portion, and is formed of a first inorganic insulating material, a first sealing layer which overlaps the first barrier layer and is formed of a second inorganic insulating material which is different from the first inorganic insulating material, and a resin layer which covers the first sealing layer and with which the gap is filled.

According to another embodiment, a display device comprises a substrate, a first lower electrode provided above the substrate, an inorganic insulating layer which covers a peripheral portion of the first lower electrode, a partition which has a lower portion provided on the inorganic insulating layer and formed of a conductive material, and an upper portion provided on the lower portion and protruding from a first side surface of the lower portion and a second side surface located on a side opposite to the first side surface, a first stacked film which includes a first organic layer being in contact with the first lower electrode, and a first upper electrode provided on the first organic layer and being in contact with the lower portion, a resin layer provided on the upper portion, a first barrier layer which overlaps the resin layer and is formed of a first inorganic insulating material, and a first sealing layer which overlaps the first barrier layer and is formed of a second inorganic insulating material which is different from the first inorganic insulating material.

The embodiments can provide a display device which can prevent the reduction in reliability.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various elements are viewed parallel to the third direction Z, the appearance is defined as a plan view.

The display device of the present embodiment is an organic electroluminescent display device comprising an organic light emitting diode (OLED) as a display element, and could be mounted on a television, a personal computer, a vehicle-mounted device, a tablet, a smartphone, a mobile phone, etc.

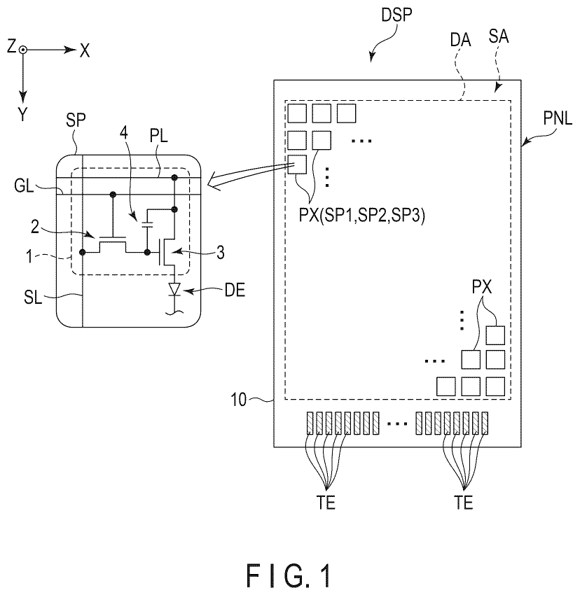

FIG. 1 is a diagram showing a configuration example of a display device DSP.

The display device DSP comprises a display panel PNL having a display area DA which displays an image and a surrounding area SA located on an external side relative to the display area DA on an insulating substrate 10. The substrate 10 may be glass or a resinous film having flexibility.

In the embodiment, the substrate 10 is rectangular in plan view. It should be noted that the shape of the substrate 10 in plan view is not limited to a rectangle and may be another shape such as a square, a circle or an oval.

The display area DA comprises a plurality of pixels PX arrayed in matrix in a first direction X and a second direction Y. Each pixel PX includes a plurality of subpixels SP. For example, each pixel PX includes subpixel SP1 which exhibits a first color, subpixel SP2 which exhibits a second color and subpixel SP3 which exhibits a third color. The first color, the second color and the third color are different colors. Each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. Each of the pixel switch 2 and the drive transistor 3 is, for example, a switching element consisting of a thin-film transistor.

The gate electrode of the pixel switch 2 is connected to a scanning line GL. One of the source electrode and drain electrode of the pixel switch 2 is connected to a signal line SL. The other one is connected to the gate electrode of the drive transistor 3 and the capacitor 4. In the drive transistor 3, one of the source electrode and the drain electrode is connected to a power line PL and the capacitor 4, and the other one is connected to the anode of the display element DE.

It should be noted that the configuration of the pixel circuit 1 is not limited to the example shown in the figure. For example, the pixel circuit 1 may comprise more thin-film transistors and capacitors.

The display element DE is an organic light emitting diode (OLED) as a light emitting element, and may be called an organic EL element.

The surrounding area SA comprises a plurality of terminals TE which are unidirectionally arranged. In the example shown in the figure, the terminals TE are arranged in the first direction X. Each of the terminals TE extends in the second direction Y. However, the configuration is not limited to this example. For example, these terminals TE are electrically connected to a flexible printed circuit or an IC chip.

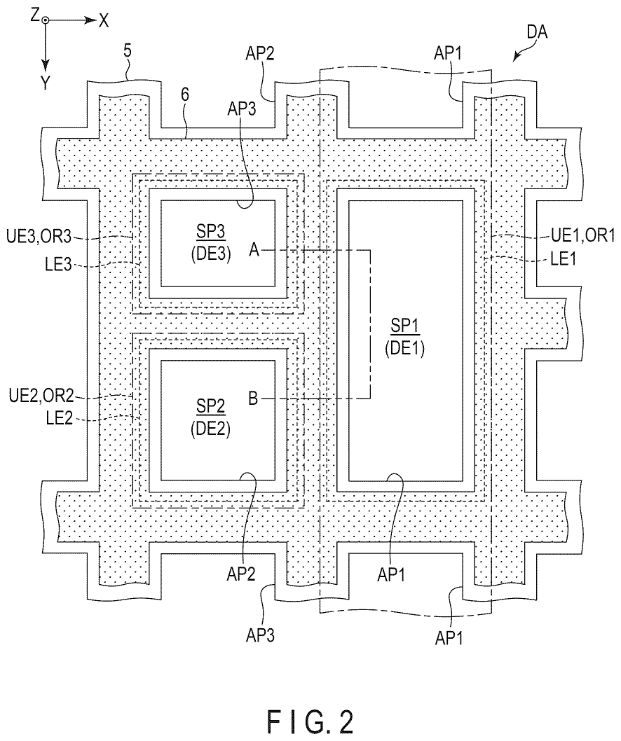

FIG. 2 is a diagram showing an example of the layout of subpixels SP1, SP2 and SP3.

In the example shown in the figure, subpixels SP2 and SP3 are arranged in the second direction Y. Subpixels SP1 and SP2 are arranged in the first direction X, and subpixels SP1 and SP3 are arranged in the first direction X.

When subpixels SP1, SP2 and SP3 are provided in line with this layout, a column in which subpixels SP2 and SP3 are alternately provided in the second direction Y and a column in which a plurality of subpixels SP1 are provided in the second direction Y are formed in the display area DA. These columns are alternately arranged in the first direction X.

It should be noted that the layout of subpixels SP1, SP2 and SP3 is not limited to the example of FIG. 2. As another example, subpixels SP1, SP2 and SP3 in each pixel PX may be arranged in order in the first direction X.

An inorganic insulating layer 5 and a partition 6 are provided in the display area DA. The inorganic insulating layer 5 has apertures AP1, AP2 and AP3 in subpixels SP1, SP2 and SP3, respectively. The inorganic insulating layer 5 having these apertures AP1, AP2 and AP3 may be called a rib.

The partition 6 overlaps the inorganic insulating layer 5 in plan view. The partition 6 is formed into a grating shape surrounding the apertures AP1, AP2 and AP3. In other words, the partition 6 has apertures in subpixels SP1, SP2 and SP3 in a manner similar to that of the inorganic insulating layer 5. The partition 6 is conductive and is electrically connected to, of the terminals TE shown in FIG. 1, each terminal TE having a common potential.

Subpixels SP1, SP2 and SP3 comprise display elements DE1, DE2 and DE3, respectively, as the display elements DE.

The display element DE1 of subpixel SP1 comprises a lower electrode LE1, an upper electrode UE1 and an organic layer OR1 overlapping the aperture AP1. The peripheral portion of the lower electrode LE1 is covered with the inorganic insulating layer 5. The lower electrode LE1, the organic layer OR1 and the upper electrode UE1 are surrounded by the partition 6 in plan view. The peripheral portion of each of the organic layer OR1 and the upper electrode UE1 overlaps the inorganic insulating layer 5 in plan view. The organic layer OR1 includes a light emitting layer which emits light in, for example, a blue wavelength range.

The display element DE2 of subpixel SP2 comprises a lower electrode LE2, an upper electrode UE2 and an organic layer OR2 overlapping the aperture AP2. The peripheral portion of the lower electrode LE2 is covered with the inorganic insulating layer 5. The lower electrode LE2, the organic layer OR2 and the upper electrode UE2 are surrounded by the partition 6 in plan view. The peripheral portion of each of the organic layer OR2 and the upper electrode UE2 overlaps the inorganic insulating layer 5 in plan view. The organic layer OR2 includes a light emitting layer which emits light in, for example, a green wavelength range.

The display element DE3 of subpixel SP3 comprises a lower electrode LE3, an upper electrode UE3 and an organic layer OR3 overlapping the aperture AP3. The peripheral portion of the lower electrode LE3 is covered with the inorganic insulating layer 5. The lower electrode LE3, the organic layer OR3 and the upper electrode UE3 are surrounded by the partition 6 in plan view. The peripheral portion of each of the organic layer OR3 and the upper electrode UE3 overlaps the inorganic insulating layer 5 in plan view. The organic layer OR3 includes a light emitting layer which emits light in, for example, a red wavelength range.

In the example shown in the figure, the outer shapes of the lower electrodes LE1, LE2 and LE3 are shown by dotted lines, and the outer shapes of the organic layers OR1, OR2 and OR3 and the upper electrodes UE1, UE2 and UE3 are shown by alternate long and short dash lines. It should be noted that the outer shape of each of the lower electrodes, organic layers and upper electrodes shown in the figure does not necessarily reflect the accurate shape.

The lower electrodes LE1, LE2 and LE3 correspond to, for example, the anodes of the display elements. The upper electrodes UE1, UE2 and UE3 correspond to the cathodes of the display elements or a common electrode and are in contact with the partition 6.

The lower electrode LE1 is electrically connected to the pixel circuit 1 (see FIG. 1) of subpixel SP1. The lower electrode LE2 is electrically connected to the pixel circuit 1 of subpixel SP2. The lower electrode LE3 is electrically connected to the pixel circuit 1 of subpixel SP3.

In the example shown in the figure, the area of the aperture AP1, the area of the aperture AP2 and the area of the aperture AP3 are different from each other. The area of the aperture AP1 is greater than that of the aperture AP2, and the area of the aperture AP2 is greater than that of the aperture AP3. In other words, the area of the lower electrode LE1 exposed from the aperture AP1 is greater than that of the lower electrode LE2 exposed from the aperture AP2. The area of the lower electrode LE2 exposed from the aperture AP2 is greater than that of the lower electrode LE3 exposed from the aperture AP3.

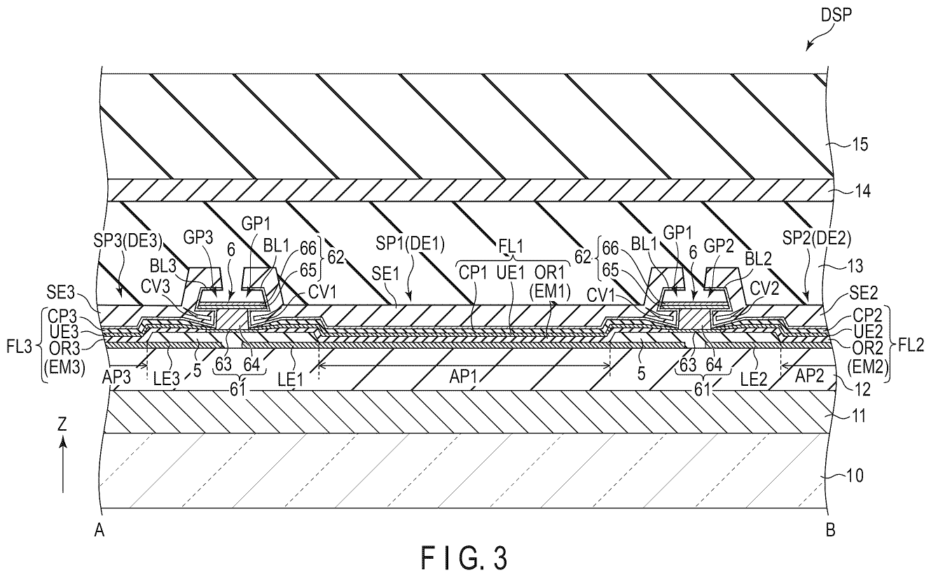

FIG. 3 is the schematic cross-sectional view of the display device DSP along the A-B line of FIG. 2.

A circuit layer 11 is provided on the substrate 10. The circuit layer 11 includes various circuits such as the pixel circuits 1 shown in FIG. 1 and various lines such as the scanning lines GL, the signal lines SL and the power lines PL. The circuit layer 11 is covered with an insulating layer 12. The insulating layer 12 is an organic insulating layer which planarizes the irregularities formed by the circuit layer 11.

The lower electrodes LE1, LE2 and LE3 are provided on the insulating layer 12 and are spaced apart from each other. The inorganic insulating layer 5 is provided on the insulating layer 12 and the lower electrodes LE1, LE2 and LE3. The aperture AP1 of the inorganic insulating layer 5 overlaps the lower electrode LE1. The aperture AP2 overlaps the lower electrode LE2. The aperture AP3 overlaps the lower electrode LE3. The peripheral portions of the lower electrodes LE1, LE2 and LE3 are covered with the inorganic insulating layer 5. The lower electrodes LE1, LE2 and LE3 are connected to the pixel circuits 1 of subpixels SP1, SP2 and SP3, respectively, through contact holes provided in the insulating layer 12. It should be noted that the contact holes of the insulating layer 12 are omitted in FIG. 3.

The partition 6 includes a conductive lower portion 61 provided on the inorganic insulating layer 5, and an upper portion 62 provided on the lower portion 61. The upper portion 62 has a width greater than that of the lower portion 61. The both end portions of the upper portion 62 protrude relative to the side surfaces of the lower portion 61. This shape of the partition 6 is called an overhang shape.

In the example shown in the figure, the lower portion 61 has a first conductive layer 63 provided on the inorganic insulating layer 5 and a second conductive layer 64 provided on the first conductive layer 63. The first conductive layer 63 is formed so as to be thinner than the second conductive layer 64. The both end portions of the first conductive layer 63 protrude from the side surfaces of the second conductive layer 64.

The upper portion 62 has a first thin film 65 provided on the second conductive layer 64 and a second thin film 66 provided on the first thin film 65. The both end portions of the first thin film 65 and the second thin film 66 protrude from the side surfaces of the second conductive layer 64.

The organic layer OR1 is in contact with the lower electrode LE1 through the aperture AP1 and covers the lower electrode LE1 exposed from the aperture AP1. The peripheral portion of the organic layer OR1 is located on the inorganic insulating layer 5. The upper electrode UE1 covers the organic layer OR1 and is in contact with the lower portion 61.

The organic layer OR2 is in contact with the lower electrode LE2 through the aperture AP2 and covers the lower electrode LE2 exposed from the aperture AP2. The peripheral portion of the organic layer OR2 is located on the inorganic insulating layer 5. The upper electrode UE2 covers the organic layer OR2 and is in contact with the lower portion 61.

The organic layer OR3 is in contact with the lower electrode LE3 through the aperture AP3 and covers the lower electrode LE3 exposed from the aperture AP3. The peripheral portion of the organic layer OR3 is located on the inorganic insulating layer 5. The upper electrode UE3 covers the organic layer OR3 and is in contact with the lower portion 61.

In the example shown in the figure, subpixel SP1 has a cap layer CP1, a barrier layer BL1 and a sealing layer SE1. Subpixel SP2 has a cap layer CP2, a barrier layer BL2 and a sealing layer SE2. Subpixel SP3 has a cap layer CP3, a barrier layer BL3 and a sealing layer SE3. The cap layers CP1, CP2 and CP3 function as optical adjustment layers which improve the extraction efficiency of the light emitted from the organic layers OR1, OR2 and OR3, respectively. It should be noted that the cap layers CP1, CP2 and CP3 may be omitted.

The cap layer CP1 is provided on the upper electrode UE1.

The cap layer CP2 is provided on the upper electrode UE2.

The cap layer CP3 is provided on the upper electrode UE3.

The barrier layer BL1 is provided on the cap layer CL1, is in contact with the lower portion 61, extends to the upper side of the upper portion 62 and forms a gap GP1 between the barrier layer BL1 and the upper portion 62.

The barrier layer BL2 is provided on the cap layer CL2, is in contact with the lower portion 61, extends to the upper side of the upper portion 62 and forms a gap GP2 between the barrier layer BL2 and the upper portion 62. The barrier layer BL2 is spaced apart from the barrier layer BL1 above the upper portion 62.

The barrier layer BL3 is provided on the cap layer CL3, is in contact with the lower portion 61, extends to the upper side of the upper portion 62 and forms a gap GP3 between the barrier layer BL3 and the upper portion 62. The barrier layer BL3 is spaced apart from the barrier layers BL1 and BL2 above the upper portion 62.

The sealing layer SE1 overlaps the barrier layer BL1, is not in contact with the partition 6 and extends to the upper side of the partition 6. In the example shown in the figure, a cavity CV1 surrounded by the sealing layer SE1 is formed at a position facing the lower portion 61 under the upper portion 62.

The sealing layer SE2 overlaps the barrier layer BL2, is not in contact with the partition 6, extends to the upper side of the partition 6 and is spaced apart from the sealing layer SE1. In the example shown in the figure, a cavity CV2 surrounded by the sealing layer SE2 is formed at a position facing the lower portion 61 under the upper portion 62.

The sealing layer SE3 overlaps the barrier layer BL3, is not in contact with the partition 6, extends to the upper side of the partition 6 and is spaced apart from the sealing layers SE1 and SE2. In the example shown in the figure, a cavity CV3 surrounded by the sealing layer SE3 is formed at a position facing the lower portion 61 under the upper portion 62.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The sealing layers SE1, SE2 and SE3 are covered with a resin layer 13. As shown in the figure, the resin layer 13 is in contact with the upper portion of the partition 6 between the sealing layer SE1 and the sealing layer SE2 and between the sealing layer SE1 and the sealing layer SE3. Each of the gap GP1 surrounded by the upper portion 62 and the barrier layer BL1, the gap GP2 surrounded by the upper portion 62 and the barrier layer BL2 and the gap GP3 surrounded by the upper portion 62 and the barrier layer BL3 is filled with the resin layer 13. In some cases, an air bubble could be present as the gap GP1, GP2 or GP3 is not completely filled with the resin layer 13.

The resin layer 13 is covered with a sealing layer 14. The sealing layer 14 is covered with an overcoat layer 15.

Each of the inorganic insulating layer 5, the barrier layers BL1, BL2 and BL3, the sealing layers SE1, SE2 and SE3 and the sealing layer 14 is formed of, for example, an inorganic insulating material such as silicon nitride (SiNx), silicon oxide (SiOx) or silicon oxynitride (SiON). A second inorganic insulating material for forming each of the sealing layers SE1, SE2 and SE3 is different from a first inorganic insulating material for forming each of the barrier layers BL1, BL2 and BL3. Regarding the dry etching of the sealing layers SE1, SE2 and SE3, the etching rate of the first inorganic insulating material is less than that of the second inorganic insulating material.

For example, each of the barrier layers BL1, BL2 and BL3 is formed of silicon oxynitride as the first inorganic insulating material. Each of the sealing layers SE1, SE2 and SE3 is formed of silicon nitride as the second inorganic insulating material. The inorganic insulating layer 5 is formed of, for example, silicon oxynitride which is the same inorganic insulating material as the barrier layers BL1, BL2 and BL3. The sealing layer 14 is formed of silicon nitride which is the same inorganic insulating material as the sealing layers SE1, SE2 and SE3.

The overcoat layer 15 is formed of the same resinous material as the resin layer 13.

The lower portion 61 of the partition 6 is formed of a conductive material and is electrically connected to each of the upper electrodes UE1, UE2 and UE3. The first conductive layer 63 is formed of, for example, a titanium-based material such as titanium or a titanium compound. The second conductive layer 64 is formed of a material which is different from that of the first conductive layer 63 and the upper portion 62, and is formed of, for example, an aluminum-based material such as aluminum or an aluminum compound.

The upper portion 62 of the partition 6 is formed of, for example, a conductive material. However, the upper portion 62 may be formed of an insulating material. The upper portion 62 is formed of a material which is different from that of the lower portion 61. The first thin film 65 is formed of, for example, a titanium-based material such as titanium or a titanium compound. The second thin film 66 is formed of, for example, an oxide conductive material such as indium tin oxide (ITO).

Each of the lower electrodes LE1, LE2 and LE3 is, for example, a multilayer body including a transparent layer formed of an oxide conductive material such as ITO and a reflective layer formed of a metal material such as silver. For example, each of the lower electrodes LE1, LE2 and LE3 is a multilayer body including a reflective layer between a pair of transparent layers.

The organic layer OR1 includes a light emitting layer EM1. The organic layer OR2 includes a light emitting layer EM2. The organic layer OR3 includes a light emitting layer EM3. The light emitting layers EM1, EM2 and EM3 are formed of materials different from each other. For example, the light emitting layer EM1 is formed of a material which emits light in a blue wavelength range. The light emitting layer EM2 is formed of a material which emits light in a green wavelength range. The light emitting layer EM3 is formed of a material which emits light in a red wavelength range.

Each of the organic layers OR1, OR2 and OR3 includes a plurality of functional layers such as a hole injection layer, a hole transport layer, an electron blocking layer, a hole blocking layer, an electron transport layer and an electron injection layer.

Each of the upper electrodes UE1, UE2 and UE3 is formed of, for example, a metal material such as an alloy of magnesium and silver (MgAg).

Each of the cap layers CP1, CP2 and CP3 is a multilayer body consisting of a plurality of thin films. All of the thin films are transparent and have refractive indices different from each other.

The circuit layer 11, insulating layer 12 and inorganic insulating layer 5 shown in the figure are provided over the display area DA and the surrounding area SA.

Now, this specification explains the manufacturing method of the display device DSP. Regarding each figure for explaining the manufacturing method, the illustration of the lower side of the insulating layer 12 is omitted.

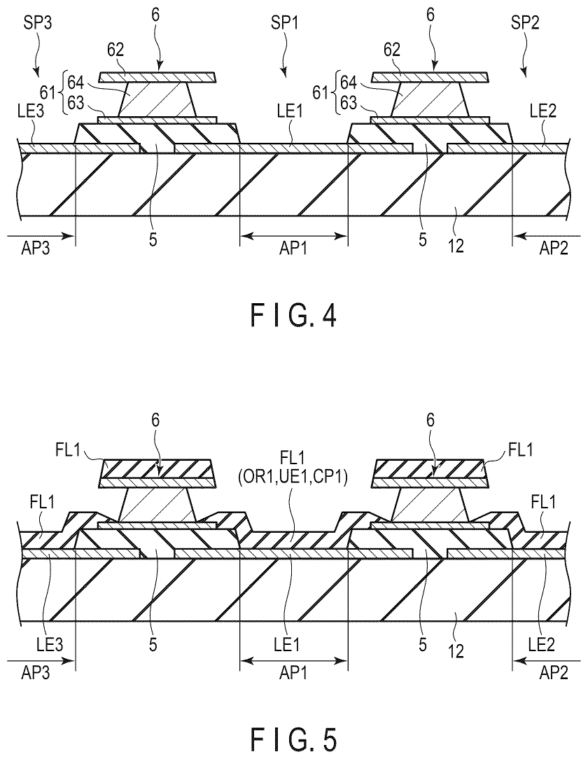

First, as shown in FIG. 4, a processing substrate SUB having the lower electrodes LE1, LE2 and LE3, the inorganic insulating layer 5 and the partition 6 is prepared. The process of forming the processing substrate SUB includes the following steps. Specifically, the circuit layer 11 and the insulating layer 12 are formed over the display area DA and the surrounding area SA on the substrate 10. Subsequently, the lower electrode LE1 of subpixel SP1, the lower electrode LE2 of subpixel SP2 and the lower electrode LE3 of subpixel SP3 are formed on the insulating layer 12. Subsequently, the inorganic insulating layer 5 which covers the peripheral portions of the lower electrodes LE1, LE2 and LE3 is formed. Subsequently, the partition 6 which has the lower portion 61 located on the inorganic insulating layer 5 and the upper portion 62 located on the lower portion 61 is formed. The first conductive layer 63 of the lower portion 61 and the upper portion 62 protrude from the side surfaces of the second conductive layer 64 of the lower portion 61. It should be noted that the process of forming the apertures AP1, AP2 and AP3 in the inorganic insulating layer 5 may be performed either before the partition 6 is formed or after the partition 6 is formed.

Subsequently, the display element DE1 is formed.

First, as shown in FIG. 5, the stacked film FL1 including the organic layer OR1, the upper electrode UE1 and the cap layer CP1 is formed. The process of forming the stacked film FL1 includes the following steps. The organic layer OR1 which is in contact with the lower electrode LE1 is formed in the aperture AP1. The process of forming the organic layer OR1 includes the process of forming each of the hole injection layer, the hole transport layer, the electron blocking layer, the light emitting layer, the hole blocking layer, the electron transport layer, the electron injection layer and the like. Subsequently, the upper electrode UE1 which covers the organic layer OR1 and is in contact with the lower portion 61 of the partition 6 is formed. Subsequently, the cap layer CP1 located on the upper electrode UE1 is formed.

Each of the organic layer OR1, the upper electrode UE1 and the cap layer CP1 is formed by vapor deposition using the partition 6 as a mask. The stacked film FL1 is divided into a plurality of portions by the partition 6 having an overhang shape. These organic layer OR1, upper electrode UE1 and cap layer CP1 are continuously formed while maintaining a vacuum environment. This stacked film FL1 is formed on the partition 6, the lower electrode LE2 and the lower electrode LE3 as well as the lower electrode LE1.

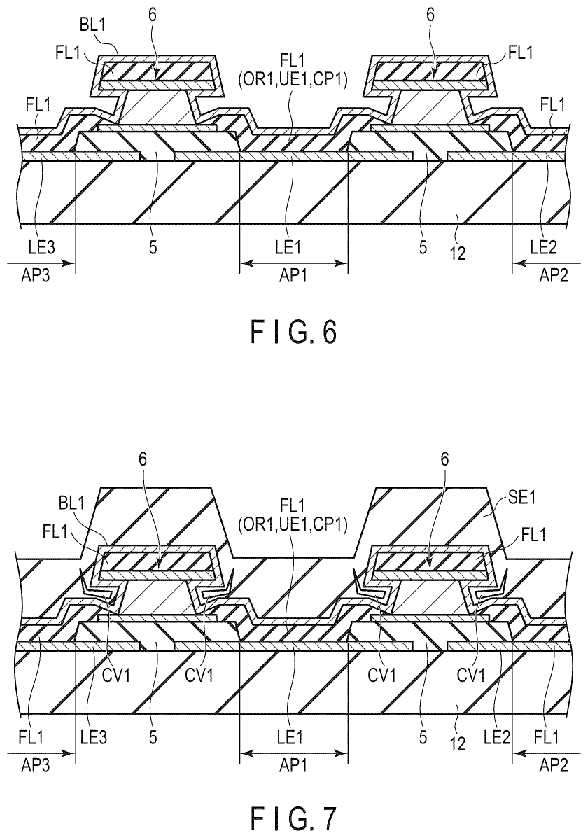

Subsequently, as shown in FIG. 6, the barrier layer BL1 is formed by depositing silicon oxynitride as the first inorganic insulating material. The barrier layer BL1 continuously covers the portions into which the stacked film FL1 is divided, and the partition 6. This barrier layer BL1 is formed by, for example, chemical vapor deposition (CVD).

Subsequently, as shown in FIG. 7, the sealing layer SE1 is formed by depositing silicon nitride as the second inorganic insulating material. The sealing layer SE1 overlaps the barrier layer BL1 so as to cover it. At this time, the cavity CV1 surrounded by the sealing layer SE1 is formed around the partition 6. This sealing layer SE1 is formed by CVD.

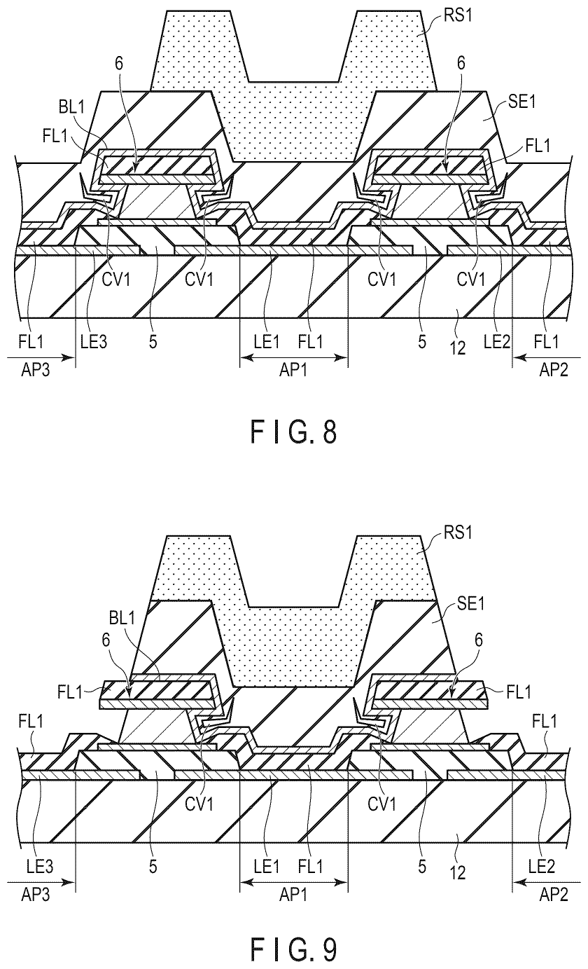

Subsequently, as shown in FIG. 8, a resist RS1 patterned into a predetermined shape is formed on the sealing layer SE1. The resist RS1 overlaps subpixel SP1 and part of the partition 6 around subpixel SP1.

Subsequently, as shown in FIG. 9, the sealing layer SE1 and the barrier layer BL1 exposed from the resist RS1 are removed by performing dry etching using the resist RS1 as a mask. By this process, on the partition 6, the stacked film FL1 is partly exposed, and further, the stacked film FL1 located on the lower electrode LE2 and the stacked film FL1 located on the lower electrode LE3 are also exposed. In the partition 6, the portion which faces the lower electrode LE2 and the portion which faces the lower electrode LE3 are also exposed.

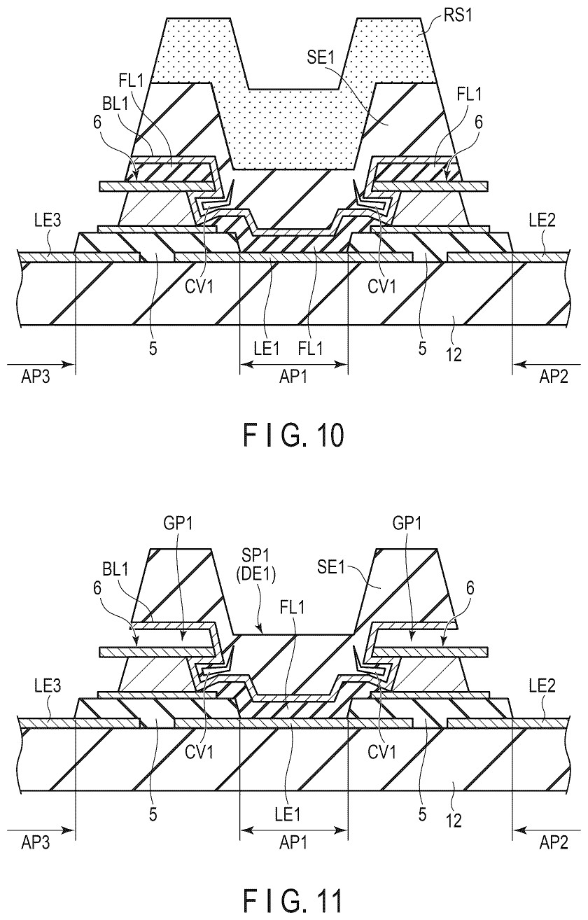

Subsequently, as shown in FIG. 10, the stacked film FL1 exposed from the resist RS1 is removed. At this time, in the stacked film FL1, the cap layer CP1, the upper electrode UE1 and the organic layer OR1 are removed in this order. By this process, the stacked film FL1 covered with the resist RS1 is left in subpixel SP1. Further, the upper portion 62 of the partition 6 is partly exposed, and the lower electrode LE2 and the lower electrode LE3 are exposed.

Subsequently, as shown in FIG. 11, the resist RS1 is removed. By this process, the display element DE1 is formed in subpixel SP1. When the resist RS1 is removed, the stacked film FL1 located on the partition 6 is also removed. In this manner, the gap GP1 is formed above the partition 6. The gap GP1 faces the lower electrode LE2 and is open. Further, the gap GP1 faces the lower electrode LE3 and is open.

Subsequently, the display element DE2 is formed. The procedure of forming the display element DE2 is similar to that of forming the display element DE1. This procedure is briefly explained below.

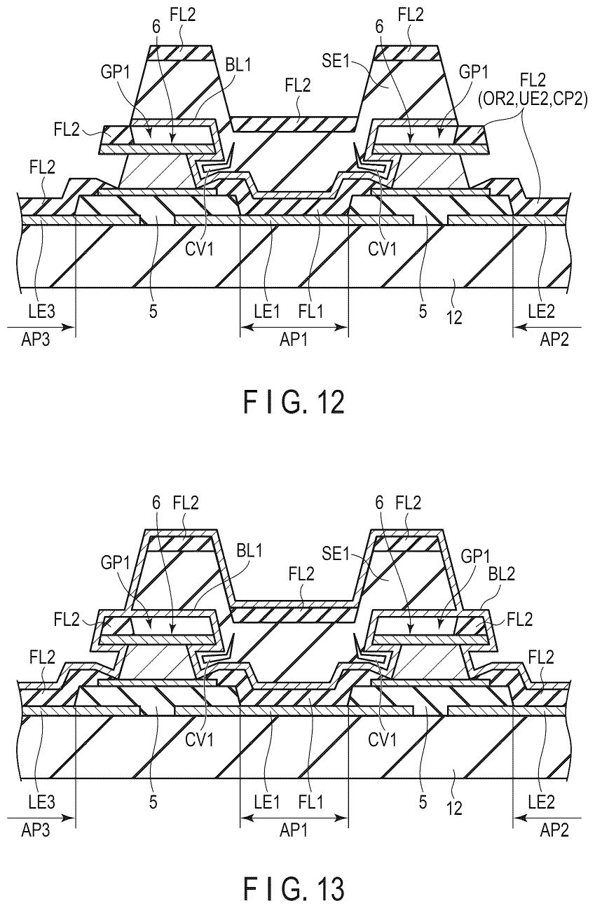

First, as shown in FIG. 12, the stacked film FL2 including the organic layer OR2, the upper electrode UE2 and the cap layer CP2 is formed on the lower electrode LE2. The stacked film FL2 is formed on the sealing layer SE1, the partition 6 and the lower electrode LE3 as well.

Subsequently, as shown in FIG. 13, the barrier layer BL2 is formed by depositing silicon oxynitride as the first inorganic insulating material. The barrier layer BL2 continuously covers the portions into which the stacked film FL2 is divided, the sealing layer SE1 and the partition 6.

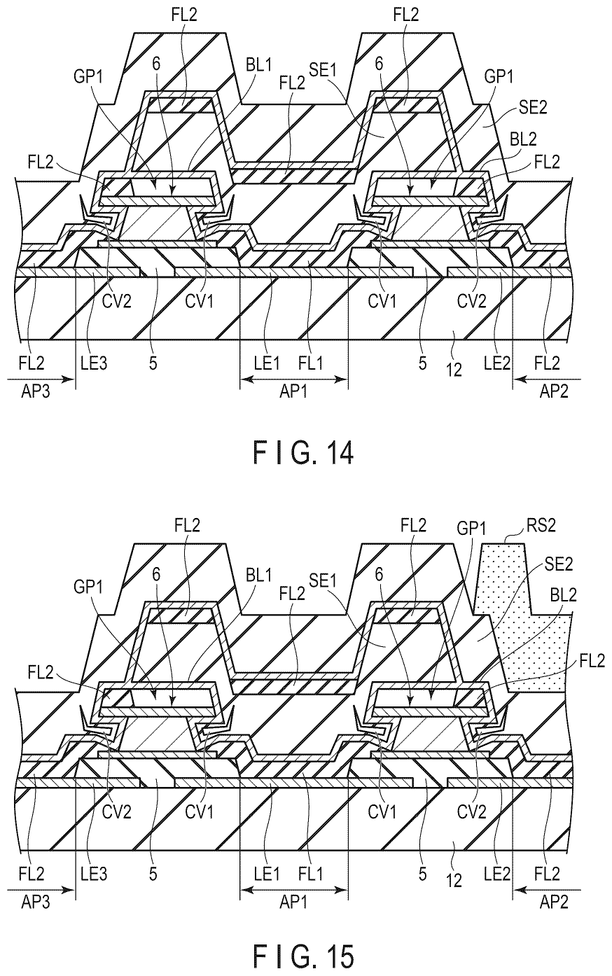

Subsequently, as shown in FIG. 14, the sealing layer SE2 is formed by depositing silicon nitride as the second inorganic insulating material. The sealing layer SE2 overlaps the barrier layer BL2 so as to cover it. At this time, the cavity CV2 surrounded by the sealing layer SE2 is formed around the partition 6.

Subsequently, as shown in FIG. 15, a resist RS2 patterned into a predetermined shape is formed on the sealing layer SE2. The resist RS2 overlaps subpixel SP2 and part of the partition 6 around subpixel SP2.

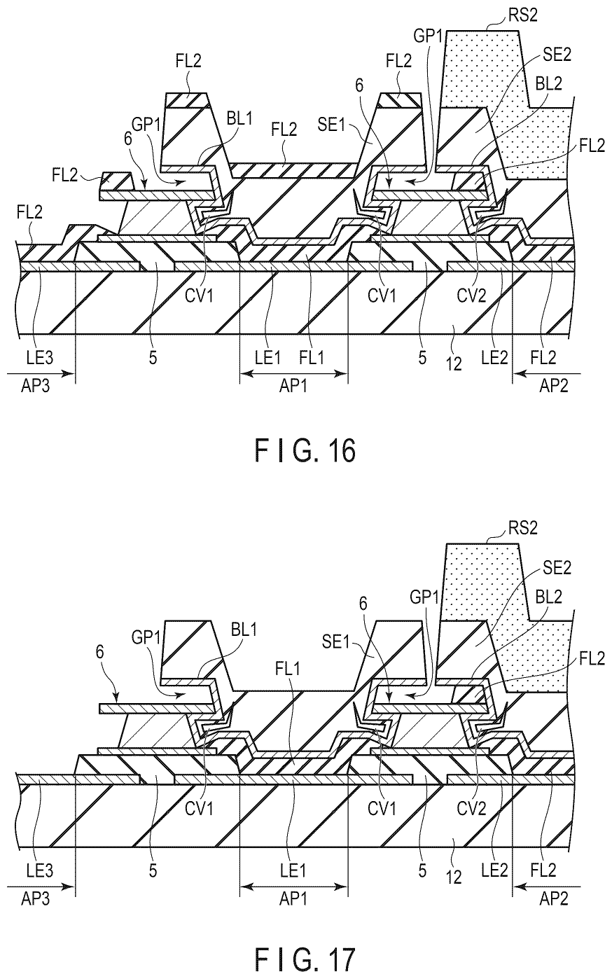

Subsequently, as shown in FIG. 16, the sealing layer SE2 and the barrier layer BL2 exposed from the resist RS2 are removed by performing dry etching using the resist RS2 as a mask. By this process, the stacked film FL2 located on the sealing layer SE1, the stacked film FL2 located on the partition 6 and the stacked film FL2 located on the lower electrode LE3 are also exposed. In the partition 6, the portion which faces the lower electrode LE3 is also exposed.

In this dry etching of the sealing layer SE2 and the barrier layer BL2, the sealing layer SE1 which is formed earlier is also easily damaged. In this regard, the gap GP1 is surrounded by the barrier layer BL1 whose etching rate is less than that of the sealing layer SE1. This configuration prevents the connection to be caused by the retraction of the sealing layer SE1 between the gap GP1 and the cavity CV1. In other words, the barrier layer BL1 and the sealing layer SE1 are interposed between the gap GP1 and the cavity CV1.

This configuration can prevent the undesired expansion of the cavity CV1 caused by the intrusion of an etching gas into the cavity CV1, and further, the exposure of the stacked film FL1 from the sealing layer SE1.

Subsequently, as shown in FIG. 17, the stacked film FL2 exposed from the resist RS2 is removed. At this time, in the stacked film FL2, the cap layer CP2, the upper electrode UE2 and the organic layer OR2 are removed in this order. By this process, the stacked film FL2 covered with the resist RS2 is left in subpixel SP2. Further, the upper portion 62 of the partition 6 is partly exposed, and the lower electrode LE3 is exposed.

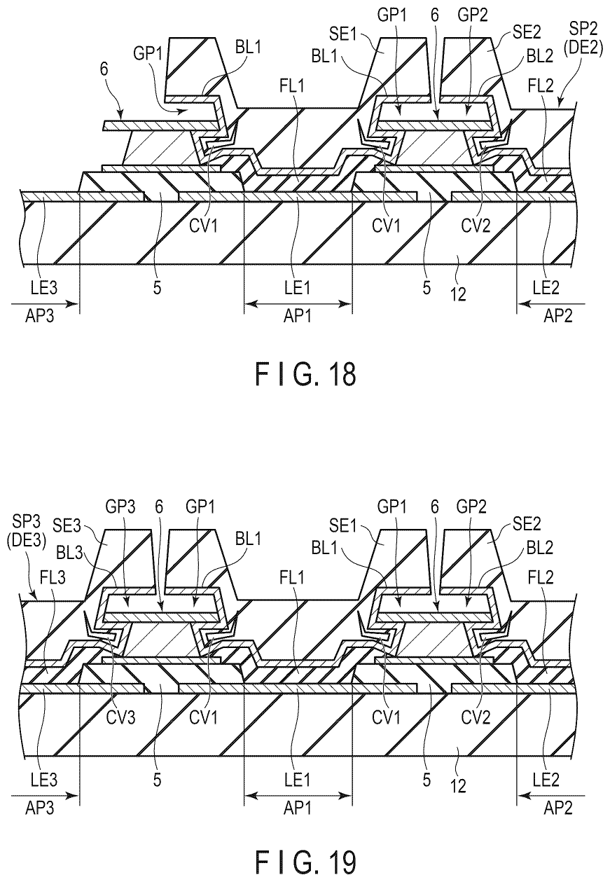

Subsequently, as shown in FIG. 18, the resist RS2 is removed. By this process, the display element DE2 is formed in subpixel SP2. When the resist RS2 is removed, the stacked film FL2 located on the partition 6 is also removed. In this manner, the gap GP2 is formed above the partition 6.

Subsequently, as shown in FIG. 19, the display element DE3 is formed. The procedure of forming the display element DE3 is similar to that of forming the display element DE1. Specifically, the stacked film FL3 including the organic layer OR3, the upper electrode UE3 and the cap layer CP3 is formed on the lower electrode LE3. Subsequently, the barrier layer BL3 is formed on the stacked film FL3, and further, the sealing layer SE3 is formed. When the sealing layer SE3 is formed, the cavity CV3 surrounded by the sealing layer SE3 is formed around the partition 6. Subsequently, a resist is formed on the sealing layer SE3. The sealing layer SE3, the barrier layer BL3, the cap layer CP3, the upper electrode UE3 and the organic layer OR3 are patterned by etching using the resist as a mask. After this patterning, the resist is removed. At this time, the gap GP3 is formed above the partition 6. By this process, the display element DE3 is formed in subpixel SP3.

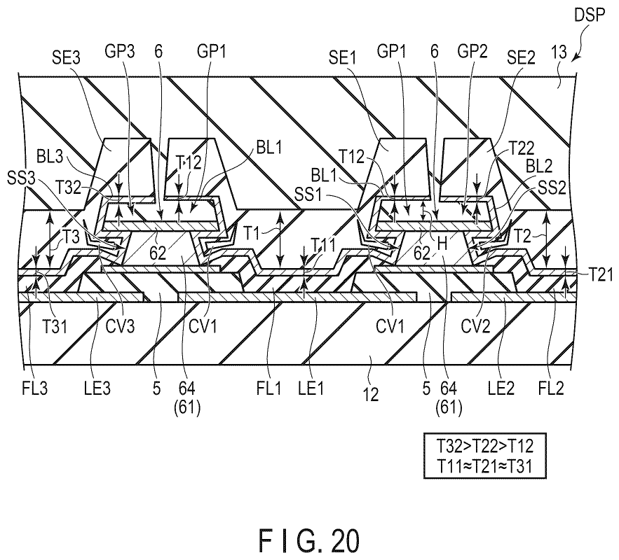

Subsequently, as shown in FIG. 20, the resin layer 13 is formed. The resin layer 13 covers the sealing layers SE1, SE2 and SE3, is put in the gaps GP1, GP2 and GP3 to fill the gaps, and is in contact with the barrier layers BL1, BL2 and BL3. Subsequently, as shown in FIG. 3, the sealing layer 14 and the overcoat layer 15 are formed in order. By this process, the display device DSP is completed.

In the manufacturing process described above, this specification assumes a case where the display element DE1 is formed firstly, and the display element DE2 is formed secondly, and the display element DE3 is formed lastly. However, the formation order of the display elements DE1, DE2 and DE3 is not limited to this example.

The display device DSP manufactured in this manner prevents the connection between the cavity CV1 and the gap GP1, the connection between the cavity CV2 and the gap GP2 and the connection between the cavity CV3 and the gap GP3. This configuration prevents the inflow of the resin layer 13 into the cavities CV1, CV2 and CV3. In addition, this configuration prevents the defective sealing of the stacked film FL1 by the sealing layer SE1, the detective sealing of the stacked film FL2 by the sealing layer SE2 and the defective sealing of the stacked film FL3 by the sealing layer SE3. In this manner, the degradation of the stacked films FL1, FL2 and FL3 by moisture is prevented, and thus, the reduction in reliability can be prevented.

Now, this specification explains the feature of the display device DSP manufactured through the above process with reference to FIG. 20.

The barrier layer BL1 overlaps the stacked film FL1 and is in contact with a side surface SS1 of the second conductive layer 64 of the lower portion 61. The resin layer 13 is provided on substantially the whole surface on the upper portion 62. Immediately above the partition 6, the barrier layer BL1 overlaps the resin layer 13, and the sealing layer SE1 overlaps the barrier layer BL1. The sealing layer SE1 is covered with the resin layer 13.

Regarding the thickness of the barrier layer BL1, thickness T11 of the barrier layer BL1 located immediately above the stacked film FL1 is less than thickness T1 of the sealing layer SE1 (T11<T1). For example, thickness T11 is 50 to 150 nm, and thickness T1 is 1000 to 3000 nm.

The barrier layer BL1 located immediately above the partition 6 could become thin when it is exposed to the etching gas in the dry etching of the sealing layers SE2 and SE3. For this reason, in the barrier layer BL1, thickness T11 is greater than thickness T12 of the barrier layer BL1 located immediately above the partition 6 (T11>T12). Thickness T12 is less than height H of the gap GP1 (or the thickness of the resin layer 13 with which the gap GP1 is filled) (H>T12).

The barrier layer BL2 overlaps the stacked film FL2 and is in contact with a side surface SS2 located on a side opposite to the side surface SS1 of the second conductive layer 64 of the lower portion 61. Immediately above the partition 6, the barrier layer BL2 overlaps the resin layer 13, and the sealing layer SE2 overlaps the barrier layer BL2. It should be noted that the barrier layers BL1 and BL2 are spaced apart from each other, and the sealing layers SE1 and SE2 are spaced apart from each other. The sealing layer SE2 is covered with the resin layer 13.

Regarding the thickness of the barrier layer BL2, thickness T21 of the barrier layer BL2 located immediately above the stacked film FL2 is less than thickness T2 of the sealing layer SE2 (T21<T2). For example, thickness T21 is almost equal to thickness T11, and thickness T2 is almost equal to thickness T1.

The barrier layer BL2 located immediately above the partition 6 could become thin when it is exposed to the etching gas in the dry etching of the sealing layer SE3. For this reason, in the barrier layer BL2, thickness T21 is greater than thickness T22 of the barrier layer BL2 located immediately above the partition 6 (T21>T22). Thickness T22 is different from thickness T12 and is greater than thickness T12 (T22>T12).

The barrier layer BL3 overlaps the stacked film FL3 and is in contact with a side surface SS3 of the second conductive layer 64 of the lower portion 61. Immediately above the partition 6, the barrier layer BL3 overlaps the resin layer 13, and the sealing layer SE3 overlaps the barrier layer BL3. It should be noted that the barrier layers BL1 and BL3 are spaced apart from each other, and the sealing layers SE1 and SE3 are spaced apart from each other. The sealing layer SE3 is covered with the resin layer 13.

Regarding the thickness of the barrier layer BL3, thickness T31 of the barrier layer BL3 located immediately above the stacked film FL3 is less than thickness T3 of the sealing layer SE3 (T31<T3). For example, thickness T31 is almost equal to thickness T11, and thickness T3 is almost equal to thickness T1.

The barrier layer BL3 located immediately above the partition 6 is not exposed to the etching gas for etching the other sealing layers. For this reason, in the barrier layer BL3, thickness T31 is almost equal to thickness T32 of the barrier layer BL3 located immediately above the partition 6 (T31≈T32). Thickness T32 is greater than thickness T12 (T32>T12).

Now, another configuration example is explained.

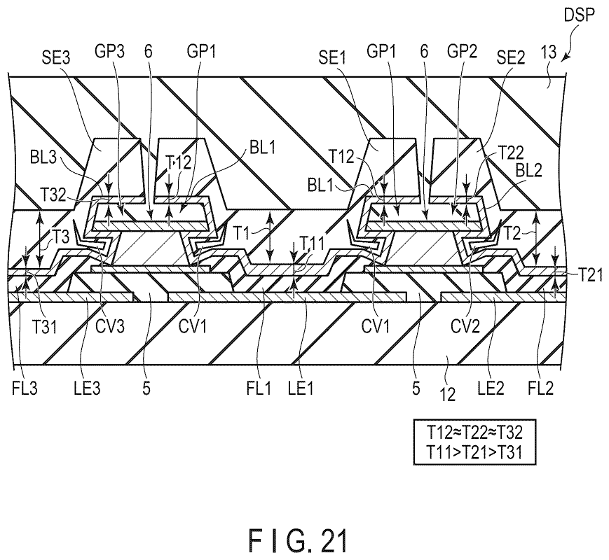

FIG. 21 is a cross-sectional view showing another configuration example of the display device DSP.

The configuration example shown in FIG. 21 is different from that shown in FIG. 20 in respect that thickness T11, thickness T21 and thickness T31 are different from each other. In the example shown in the figure, it is assumed that the display element DE1, the display element DE2 and the display element DE3 are formed in this order. Thickness T21 is less than thickness T11, and thickness T31 is less than thickness T21 (T11>T21>T31). Immediately above the partition 6, thickness T12, thickness T22 and thickness T32 are almost equal to each other (T12≈T22≈T32). It should be noted that, thickness T11 is greater than thickness T12 (T11>T12), and thickness T21 is greater than thickness T22 (T21>T22), and thickness T31 is almost equal to thickness T32 (T31≈T32).

In this configuration example, in a manner similar to that of the configuration example shown in FIG. 20, each of the gaps GP1, GP2 and GP3 is filled with the resin layer 13. Further, the barrier layer BL1 and the sealing layer SE1 are interposed between the gap GP1 and the cavity CV1. The barrier layer BL2 and the sealing layer SE2 are interposed between the gap GP2 and the cavity CV2. The barrier layer BL3 and the sealing layer SE3 are interposed between the gap GP3 and the cavity CV3. For this reason, effects similar to those of the above configuration example are obtained.

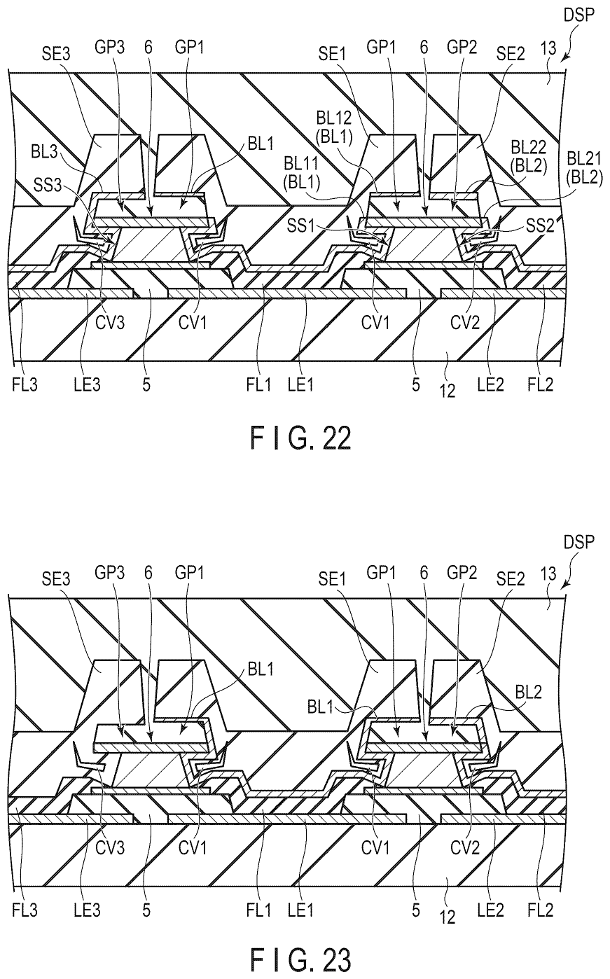

FIG. 22 is a cross-sectional view showing another configuration example of the display device DSP.

The configuration example shown in FIG. 22 is different from that shown in FIG. 20 in respect that the barrier layer BL1 is separated into a first part BL11 which is in contact with the side surface SS1 and a second part BL12 which extends on the upper side of the partition 6 (or the portion which overlaps the resin layer 13). In other words, the resin layer 13 with which the gap GP1 is filled is in contact with the sealing layer SE1 between the first part BL11 and the second part BL12. This feature is formed when part of the barrier layer BL1 surrounding the gap GP1 (the portion whose thickness is locally less) is removed in the dry etching of the sealing layers SE2 and SE3.

In the example shown in the figure, the barrier layer BL2 is separated into a first part BL21 which is in contact with the side surface SS2 and a second part BL22 which extends on the upper side of the partition 6 (or the portion which overlaps the resin layer 13). The resin layer 13 is in contact with the sealing layer SE2 between the first part BL21 and the second part BL22. This feature is formed when part of the barrier layer BL2 surrounding the gap GP2 (the portion whose thickness is locally less) is removed in the dry etching of the sealing layer SE3.

It should be noted that, in the barrier layer BL3, the portion which is in contact with the side surface SS3 and the portion which extends on the upper side of the partition 6 are continuously formed without being separated from each other.

In this configuration example, in a manner similar to that of the configuration example shown in FIG. 20, each of the gaps GP1, GP2 and GP3 is filled with the resin layer 13. Further, the sealing layer SE1 is interposed between the gap GP1 and the cavity CV1. The sealing layer SE2 is interposed between the gap GP2 and the cavity CV2. The sealing layer SE3 is interposed between the gap GP3 and the cavity CV3. For this reason, effects similar to those of the above configuration example are obtained.

FIG. 23 is a cross-sectional view showing another configuration example of the display device DSP.

The configuration example shown in FIG. 23 is different from that shown in FIG. 20 in respect that the barrier layer BL3 is omitted. As described above, when the display element DE1, the display element DE2 and the display element DE3 are formed in this order, the sealing layer SE3 is not exposed to the etching gas for etching the other sealing layers. Therefore, even if the barrier layer BL3 is omitted, the undesired retraction of the sealing layer SE3 is prevented, thereby preventing the connection between the gap GP3 and the cavity CV3 and the exposure of the sealing film FL3 from the sealing layer SE3. Thus, in this configuration example, effects similar to those of the configuration example described above are obtained.

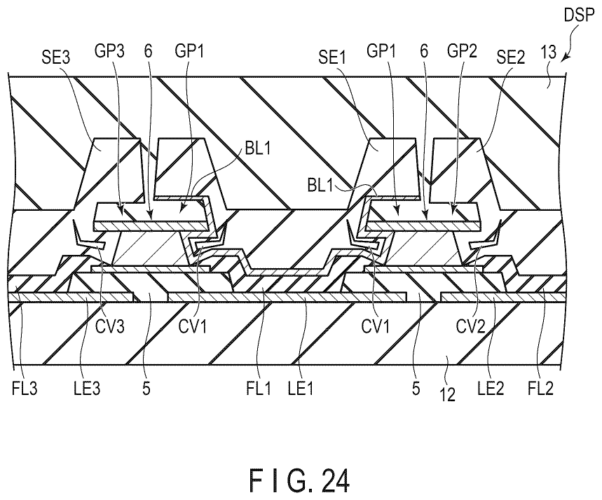

FIG. 24 is a cross-sectional view showing another configuration example of the display device DSP.

The configuration example shown in FIG. 24 is different from that shown in FIG. 23 in respect that the barrier layer BL2 is omitted in addition to the barrier layer BL3. In this configuration example, effects similar to those of the configuration example described above are obtained.

In the embodiment described above, for example, the lower electrode LE1 corresponds to a first lower electrode, and the lower electrode LE2 corresponds to a second lower electrode. The organic layer OR1 corresponds to a first organic layer, and the organic layer OR2 corresponds to a second organic layer. The upper electrode UE1 corresponds to a first upper electrode, and the upper electrode UE2 corresponds to a second upper electrode. In the partition 6, the side surface SS1 corresponds to a first side surface, and the side surface SS2 corresponds to a second side surface. The stacked film FL1 corresponds to a first stacked film, and the stacked film FL2 corresponds to a second stacked film. The barrier layer BL1 corresponds to a first barrier layer, and the barrier layer BL2 corresponds to a second barrier layer. The sealing layer SE1 corresponds to a first sealing layer, and the sealing layer SE2 corresponds to a second sealing layer.

As explained above, the present embodiment can provide a display device which can prevent the reduction in reliability.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or by adding or omitting a step or changing the condition of a step, all of the modifications fall within the scope of the present invention as long as they are in keeping with the spirit of the invention.

Further, other effects which may be obtained from the above embodiments and are self-explanatory from the descriptions of the specification or can be arbitrarily conceived by a person of ordinary skill in the art are considered as the effects of the present invention as a matter of course.

What is claimed is:

1. A display device comprising:
a substrate;
a first lower electrode provided above the substrate;
an inorganic insulating layer which covers a peripheral portion of the first lower electrode;
a partition which has a lower portion provided on the inorganic insulating layer and formed of a conductive material, and an upper portion provided on the lower portion and protruding from a first side surface of the lower portion and a second side surface located on a side opposite to the first side surface;
a first stacked film which includes a first organic layer being in contact with the first lower electrode, and a first upper electrode provided on the first organic layer and being in contact with the lower portion;
a first barrier layer which is provided on the first stacked film, is in contact with the first side surface, extends to an upper side of the partition, forms a gap between the first barrier layer and the upper portion, and is formed of a first inorganic insulating material;
a first sealing layer which overlaps the first barrier layer and is formed of a second inorganic insulating material which is different from the first inorganic insulating material; and
a resin layer which covers the first sealing layer and with which the gap is filled.

2. The display device of claim 1, wherein
an etching rate of the first inorganic insulating material is less than an etching rate of the second inorganic insulating material.

3. The display device of claim 1, wherein
the first inorganic insulating material is silicon oxynitride, and
the second inorganic insulating material is silicon nitride.

4. The display device of claim 1, wherein
a thickness of the first barrier layer located immediately above the first stacked film is greater than a thickness of the first barrier layer located immediately above the partition.

5. The display device of claim 1, wherein
a thickness of the first barrier layer located immediately above the partition is less than a height of the gap.

6. The display device of claim 1, further comprising:
a second lower electrode which is provided above the substrate and has a peripheral portion covered with the inorganic insulating layer;
a second stacked film which includes a second organic layer being in contact with the second lower electrode, and a second upper electrode provided on the second organic layer and being in contact with the lower portion;
a second barrier layer which is provided on the second stacked film, is in contact with the second side surface, extends to an upper side of the partition, forms a gap between the second barrier layer and the upper portion, is spaced apart from the first barrier layer and is formed of the first inorganic insulating material; and
a second sealing layer which overlaps the second barrier layer, is spaced apart from the first sealing layer and is formed of the second inorganic insulating material, wherein
a thickness of the second barrier layer located immediately above the partition is greater than a thickness of the first barrier layer located immediately above the partition.

7. The display device of claim 6, wherein
a thickness of the second barrier layer located immediately above the second stacked film is substantially equal to a thickness of the first barrier layer located immediately above the first stacked film.

8. The display device of claim 1, further comprising:
a second lower electrode which is provided above the substrate and has a peripheral portion covered with the inorganic insulating layer;
a second stacked film which includes a second organic layer being in contact with the second lower electrode, and a second upper electrode provided on the second organic layer and being in contact with the lower portion;
a second barrier layer which is provided on the second stacked film, is in contact with the second side surface, extends to an upper side of the partition, forms a gap between the second barrier layer and the upper portion, is spaced apart from the first barrier layer and is formed of the first inorganic insulating layer; and
a second sealing layer which overlaps the second barrier layer, is spaced apart from the first sealing layer and is formed of the second inorganic insulating material, wherein
a thickness of the second barrier layer located immediately above the second stacked film is less than a thickness of the first barrier layer located immediately above the first stacked film.

9. The display device of claim 8, wherein
a thickness of the second barrier layer located immediately above the partition is substantially equal to a thickness of the first barrier layer located immediately above the partition.

10. The display device of claim 1, further comprising a cavity which is surrounded by the first sealing layer and faces the first side surface, wherein the first barrier layer and the first sealing layer are interposed between the gap and the cavity.

11. The display device of claim 1, wherein
the first barrier layer is separated into a first part which is in contact with the first side surface, and a second part which extends on an upper side of the partition, and
the resin layer with which the gap is filled is in contact with the first sealing layer between the first part and the second part.

12. The display device of claim 11, further comprising a cavity which is surrounded by the first sealing layer and faces the first side surface, wherein the first sealing layer is interposed between the gap and the cavity.

13. A display device comprising:
a substrate;
a first lower electrode provided above the substrate;
an inorganic insulating layer which covers a peripheral portion of the first lower electrode;
a partition which has a lower portion provided on the inorganic insulating layer and formed of a conductive material, and an upper portion provided on the lower portion and protruding from a first side surface of the lower portion and a second side surface located on a side opposite to the first side surface;
a first stacked film which includes a first organic layer being in contact with the first lower electrode, and a first upper electrode provided on the first organic layer and being in contact with the lower portion;
a resin layer provided on the upper portion;
a first barrier layer which overlaps the resin layer and is formed of a first inorganic insulating material; and
a first sealing layer which overlaps the first barrier layer and is formed of a second inorganic insulating material which is different from the first inorganic insulating material.

14. The display device of claim 13, further comprising:
a second barrier layer which overlaps the resin layer, is spaced apart from the first barrier layer and is formed of the first inorganic insulating material; and
a second sealing layer which overlaps the second barrier layer, is spaced apart from the first sealing layer and is formed of the second inorganic insulating material.

15. The display device of claim 14, wherein
a thickness of the first barrier layer is different from a thickness of the second barrier layer.

16. The display device of claim 14, wherein
the first sealing layer and the second sealing layer are covered with the resin layer.
